(19) United States
(12) Patent Application Publication
(10) Pub. No.: US 2024/0329124 A1
(43) Pub. Date: Oct. 3, 2024

(54) SEMICONDUCTOR DEVICE AND DRIVER DEVICE

(71) Applicant: LAPIS Technology Co., Ltd., Yokohama (JP)

(72) Inventor: Kunihiro HARAYAMA, Yokohama (JP)

(73) Assignee: LAPIS Technology Co., Ltd., Yokohama (JP)

(21) Appl. No.: 18/607,597

(22) Filed: Mar. 18, 2024

(30) Foreign Application Priority Data
Mar. 31, 2023 (JP) 2023-058114

(51) Int. Cl. G01R 31/28; H03K 3/037

(52) U.S. Cl. CPC G01R 31/2884; H03K 3/037

(57) ABSTRACT

A semiconductor device includes a test circuit, a register provided in a circuit different from the test circuit, an electrode connectable to the outside of the semiconductor device, and a substrate that has the electrode, the register, and the test circuit mounted thereon and includes a semiconductor, the test circuit includes a test logic circuit that includes the same transistor connection as the register, a collation circuit that collates a logic value of an output signal of the test logic circuit with a logic value of an output signal from an expected value providing circuit, and an alert circuit that, in a case where the collation of the collation circuit indicates a mismatch, generates an alert signal indicating this mismatch, the test logic circuit is configured to store a logic value to be collated, and the register is connected to the electrode through one or more circuits or directly.

### CROSS-REFERENCE TO RELATED APPLICATION

This application claims the priority benefit of Japan application serial no. 2023-058114, filed on Mar. 31, 2023. The entirety of the above-mentioned patent application is hereby incorporated by reference herein and made a part of this specification.

### BACKGROUND

### Technical Field

The disclosure relates to a semiconductor device and a driver device.

### Related Art

Patent Document 1 (Japanese Patent Application Laid-Open No. 2007-058467) discloses a register monitoring circuit. The register monitoring circuit prevents a device from performing undesired operations due to changes in the content of a register caused by bit corruptions or abnormal writes.

Semiconductor integrated circuits are used in various environments and for various purposes. A driver circuit used in a semiconductor integrated circuit, for example, a display panel, writes image data for each line of the display panel. Further, the driver circuit writes setting data necessary for image quality expression (for example, gamma curve setting data) and setting data necessary for maintaining a display system separately from the image data, and holds the data in an internal register.

A system including a display panel may be exposed to electrostatic discharge (ESD). Electrostatic discharge in the driver circuit can lead to data corruptions in the internal register of the driver circuit. An unintended change in the internal register may influence a display image.

The following are several measures for reducing the influence of data corruption. One involves periodically resetting and rewriting registers. Alternatively, another involves collating register data written inside a register with the content of another register, and rewriting the register in a case where an abnormality is detected. Alternatively, another involves writing the same data into a plurality of registers and rewriting these registers when a mismatch occurs in data of the registers.

### SUMMARY

According to a first aspect of the disclosure, there is provided a semiconductor device including: at least one test circuit connected to a low-potential power supply line and a high-potential power supply line; a register provided in a circuit different from the test circuit and connected to the low-potential power supply line and the high-potential power supply line; an electrode configured to enable at least one of inputting and outputting a signal and connectable to the outside of the semiconductor device; and a substrate that has the electrode, the register, and the test circuit mounted thereon and includes a semiconductor, wherein the test circuit includes at least one test logic circuit that includes the same transistor connection as the register, at least one collation circuit that receives an output signal of the test logic circuit and an output signal from an expected value providing circuit and collates a logic value of the output signal of the test logic circuit with a logic value of the output signal from the expected value providing circuit, and an alert circuit that, in a case where the collation circuit indicates a mismatch of the collation, generates an alert signal indicating the mismatch, the test logic circuit is configured to store a logic value to be collated, and the register is connected to the electrode through one or a plurality of circuits or directly.

According to a second aspect of the disclosure, there is provided a driver device including: the semiconductor device according to the above aspect; a receiver provided on the substrate; a setting circuit that receives setting data for gamma curve setting from the receiver through the register and is provided on the substrate; and a driver circuit configured to receive the setting data from the setting circuit and to drive a display, and provided on the substrate, wherein a collation result of the collation circuit is output to the outside of the substrate.

### BRIEF DESCRIPTION OF THE DRAWINGS

FIG. 1 is a diagram schematically illustrating a semiconductor device according to the present embodiment.

FIG. 2 is a diagram illustrating an exemplary test circuit of the semiconductor device according to the present embodiment.

FIG. 3 is a diagram illustrating operating waveforms of the exemplary test circuit shown in FIG. 2.

FIG. 4 is a diagram illustrating an exemplary test circuit of the semiconductor device according to the present embodiment.

FIG. 5 is a diagram illustrating an exemplary test circuit of the semiconductor device according to the present embodiment.

FIG. 6 is a diagram illustrating operating waveforms of the exemplary test circuit shown in FIG. 5.

FIG. 7 is a diagram schematically illustrating the arrangement of the exemplary test circuits shown in FIG. 5.

FIG. 8 is a diagram illustrating an exemplary test logic circuit of the semiconductor device according to the present embodiment.

FIG. 9 is a diagram illustrating an exemplary test logic circuit of the semiconductor device according to the present embodiment.

FIG. 10 is a diagram illustrating an exemplary test logic circuit of the semiconductor device according to the present embodiment.

FIG. 11 is a diagram illustrating an exemplary test logic circuit of the semiconductor device according to the present embodiment.

FIG. 12 is a diagram schematically illustrating a driver device according to the present embodiment.

### DESCRIPTION OF THE EMBODIMENTS

Embodiments of the disclosure provide a semiconductor device capable of detecting the possibility of data corruption in a register configured to statically hold data, and a driver device including the semiconductor device.

Hereinafter, each embodiment for carrying out the disclosure will be described with reference to the accompanying drawings. In the subsequent description, the same or similar parts are denoted by the same or similar reference numerals and signs, and description thereof will not be repeated.

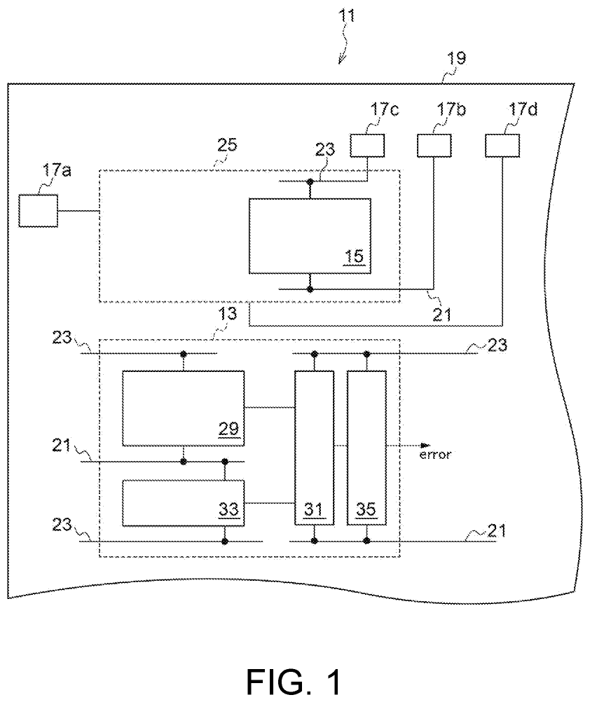

FIG. 1 is a diagram schematically illustrating a semiconductor device according to the present embodiment.

A semiconductor device 11 includes a test circuit 13, a register 15, electrodes 17 (17a, 17b, 17c, 17d), and a substrate 19 including semiconductors. The register 15 is provided in a circuit 25 different from the test circuit 13.

The electrode 17a can be, for example, a pad electrode, and is configured to enable at least one of inputting and outputting a signal and to be connectable to the outside of the semiconductor device 11. The electrode 17a can be connected to the register 15, for example, one of its input and output, through one or a plurality of circuits or directly. The electrode 17d can be connected to the register 15, for example, the other of its input and output, through one or a plurality of circuits or directly.

The test circuit 13 and the register 15 are connected to a low-potential power supply line 21 and a high-potential power supply line 23. The low-potential power supply line 21 and the high-potential power supply line 23 are connected to the electrode 17b and the electrode 17c, respectively. The substrate 19 carries the test circuit 13, the register 15, the electrode 17a, the electrode 17b, the electrode 17c, and the electrode 17d, which are located within the same semiconductor chip.

The test circuit 13 includes at least one test logic circuit 29 and at least one collation circuit 31. The test logic circuit 29 is configured to store a logic value to be collated. The collation circuit 31 receives an output signal of the test logic circuit 29 and an output signal from an expected value providing circuit 33, and collates the logic value of the output signal of the test logic circuit 29 with the logic value of the output signal from the expected value providing circuit 33. In a case where this collation indicates a mismatch, the test circuit 13 can generate an alert signal (error) indicating a mismatch. The test circuit 13 is provided with an alert circuit 35, and the alert circuit 35 generates an alert signal.

According to the semiconductor device 11, a mismatch in data collation in the test circuit 13 indicates the possibility of data corruption in the register 15. The register 15 is required to be updated. The register 15 can be updated in response to an alert signal.

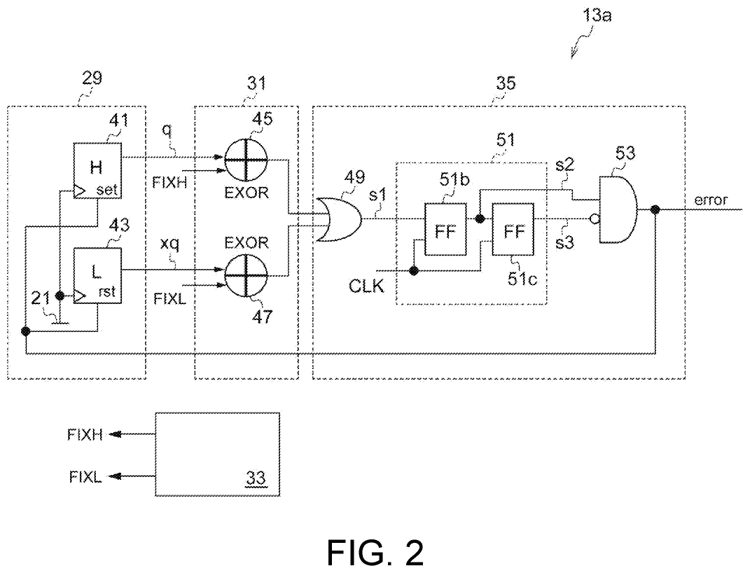

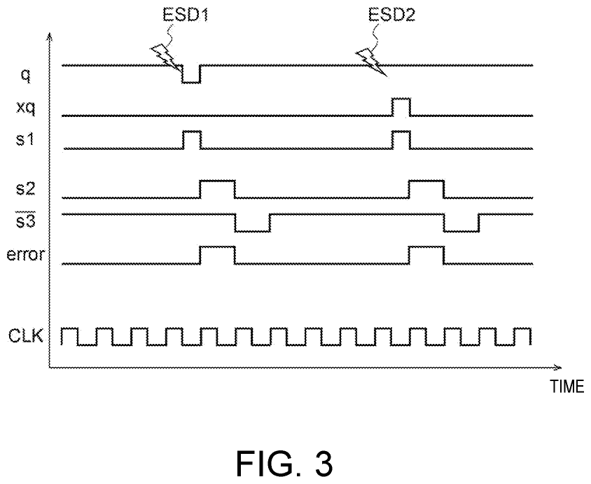

FIG. 2 is a diagram illustrating an exemplary test circuit of the semiconductor device according to the present embodiment. FIG. 3 is a diagram illustrating operating waveforms of the exemplary test circuit shown in FIG. 2. Referring to FIG. 3, data disturbances ESD1 and ESD2 are shown.

In a test circuit 13a, the test logic circuit 29 can include a first test logic circuit 41 and a second test logic circuit 43. One of the first test logic circuit 41 and the second test logic circuit 43, for example, the first test logic circuit 41, is configured to hold a logic value “H.” The other of the first test logic circuit 41 and the second test logic circuit 43, for example, the second test logic circuit 43, is configured to hold a logic value “L.”

The first test logic circuit 41 and the second test logic circuit 43 can include, for example, a flip-flop circuit or a latch circuit. Each of the first test logic circuit 41 and the second test logic circuit 43 which are exemplary can include a flip-flop circuit. Specifically, the first test logic circuit 41 includes a flip-flop circuit configured to hold the logic value “H,” and the second test logic circuit 43 includes a flip-flop circuit configured to hold the logic value “L.”

The collation circuit 31 includes a first collation circuit 45 and a second collation circuit 47.

The first collation circuit 45 receives an output signal (q) of the first test logic circuit 41 and an expected value signal (FIXH) of the expected value providing circuit 33, and collates the logic value of the output signal (q) of the first test logic circuit 41 with the logic value “H” of the expected value signal of the expected value providing circuit 33.

The second collation circuit 47 receives an output signal (xq) of the second test logic circuit 43 and an expected value signal (FIXL) of the expected value providing circuit 33, and collates the logic value of the output signal (xq) of the second test logic circuit 43 with the logic value “L” of the expected value signal (FIXL) of the expected value providing circuit 33.

The logic value of the expected value signal of the exemplary expected value providing circuit 33 is such that the signal FIXH having a logic value “H” is imparted to the first collation circuit 45 and the signal FIXL having a logic value “L” is imparted to the second collation circuit 47. The first collation circuit 45 and the second collation circuit 47 which are exemplary can include an exclusive OR circuit (EXOR).

The outputs of the first collation circuit 45 and the second collation circuit 47 are imparted to a first logic circuit 49, and the first logic circuit 49 generates a determination signal (s1) indicating whether an expected value mismatch has occurred in at least one of the first collation circuit 45 and the second collation circuit 47. The exemplary first logic circuit 49 can include an OR gate.

The alert circuit 35 includes a delay circuit 51 and a second logic circuit 53 in addition to the first logic circuit 49. The output of the logic circuit 49 is imparted to the delay circuit 51 in order to detect transitions in the output of the logic circuit 49. The exemplary delay circuit 51 includes a plurality of flip-flop circuits (51b, 51c) that operates in accordance with a clock CLK, and these flip-flop circuits are connected in series. The second logic circuit 53 has a plurality of inputs, and these inputs are connected to different intermediate nodes (s2, s3) in the series connection of flip-flop circuits within the delay circuit 51. The second logic circuit 53 generates a signal (error) indicating a collation result from the transition waveform at the output of the first logic circuit 49.

As shown in FIG. 3, the test circuit 13a can detect data corruptions in at least one of the first test logic circuit 41 and the second test logic circuit 43.

The output of the second logic circuit 53 is connected to the set terminal (set) of the first test logic circuit 41 and the reset terminal (rst) of the second test logic circuit 43, and the detection result is fed back. In response to this feedback, the initial logic values of the first test logic circuit 41 and the second test logic circuit 43 are set again when a data corruption is detected.

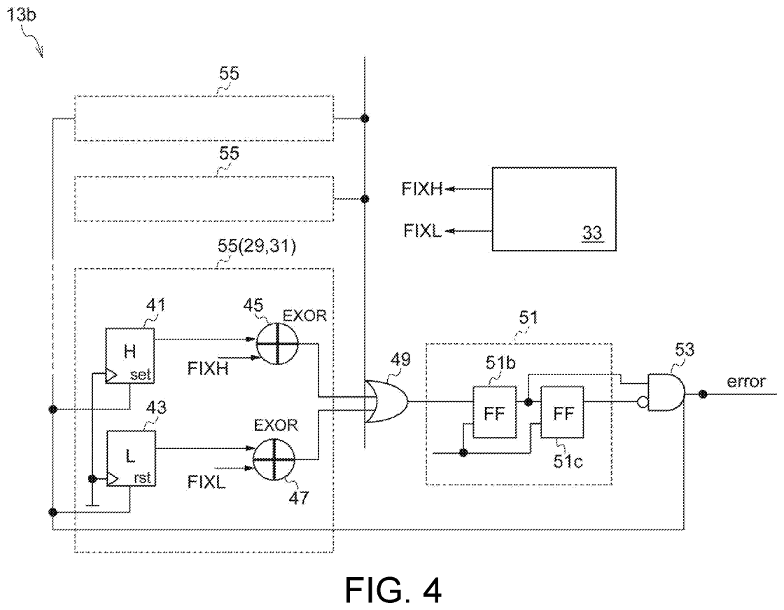

FIG. 4 is a diagram illustrating an exemplary test circuit of the semiconductor device according to the present embodiment. Referring to FIG. 4, in a test circuit 13b, the test logic circuit 29 and the collation circuit 31 constitute a unit 55.

The test circuit 13b includes a plurality of units 55 and the first logic circuit 49 connected to the outputs of these units 55. The first logic circuit 49 is a multi-input logic gate that receives all of the signals from the outputs of a plurality of units 55. According to the test circuit 13b, the accuracy of detection of data corruptions can be improved.

The plurality of units 55 can be located at various positions on the semiconductor chip of the semiconductor device 11. The test circuit 13b can detect the occurrence of data corruptions in at least one of the units 55.

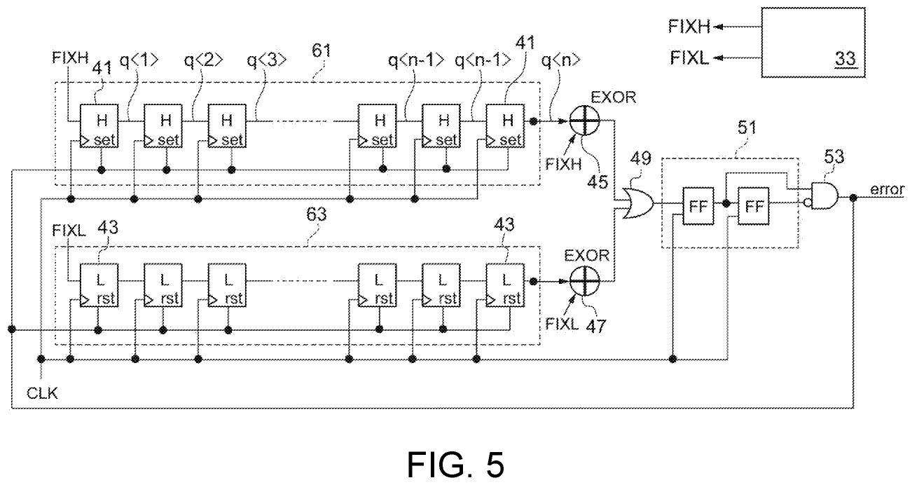

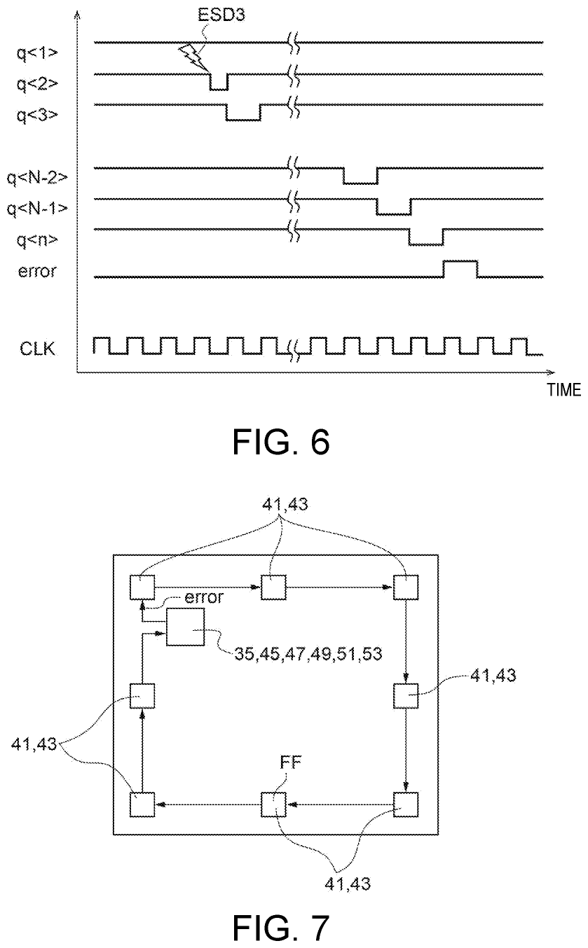

FIG. 5 is a diagram illustrating an exemplary test circuit of the semiconductor device according to the present embodiment. FIG. 6 is a diagram illustrating operating waveforms of the exemplary test circuit shown in FIG. 5. Referring to FIG. 6, a data disturbance ESD3 is shown.

Referring to FIG. 5, a plurality of first test logic circuits 41 is connected in cascode to constitute a first cascode-type logic circuit 61. In addition, a plurality of second test logic circuits 43 is connected in cascode to constitute a second cascode-type logic circuit 63.

The exemplary first test logic circuit 41 in the first cascode-type logic circuit 61 can include a flip-flop circuit. Specifically, the first test logic circuit 41 at the first stage includes a flip-flop circuit configured to hold the logic value “H,” and the first test logic circuits 41 at the second and subsequent stages include cascode-connected flip-flop circuits configured to hold the logic value “H.” The exemplary second test logic circuit 43 in the second cascode-type logic circuit 63 can include a flip-flop circuit. Specifically, the second test logic circuit 43 at the first stage includes a flip-flop circuit configured to hold the logic value “L,” and the second test logic circuits 43 at the second and subsequent stages include cascode-connected flip-flop circuits configured to hold the logic value “L.”

As shown in FIG. 6, data corruption occurs at the node q<2> of the first cascode-type logic circuit 61 due to the data disturbance ESD3. This data corruption propagates in the first cascode-type logic circuit 61 in accordance with the clock CLK. Finally, it reaches the first collation circuit 45.

FIG. 7 is a diagram schematically illustrating the arrangement of the exemplary test circuits shown in FIG. 5. As shown in FIG. 7, the first cascode-type logic circuit 61 and the second cascode-type logic circuit 63 can have the same number of stages connected in series. The corresponding flip-flop circuits of the stages can be arranged apart from each other on the semiconductor chip of the semiconductor device 11. The outputs of the first cascode-type logic circuit 61 and the second cascode-type logic circuit 63 can be connected to a single collation circuit 31. The output of the second logic circuit 53 is connected to the inputs of the first cascode-type logic circuit 61 and the second cascode-type logic circuit 63, specifically, the set terminal of the first test logic circuit 41 and the reset terminal of the second test logic circuit 43, and the detection result is fed back. In response to this feedback, each logic value is set again in the first test logic circuit 41 and the second test logic circuit 43 during detection of data corruptions.

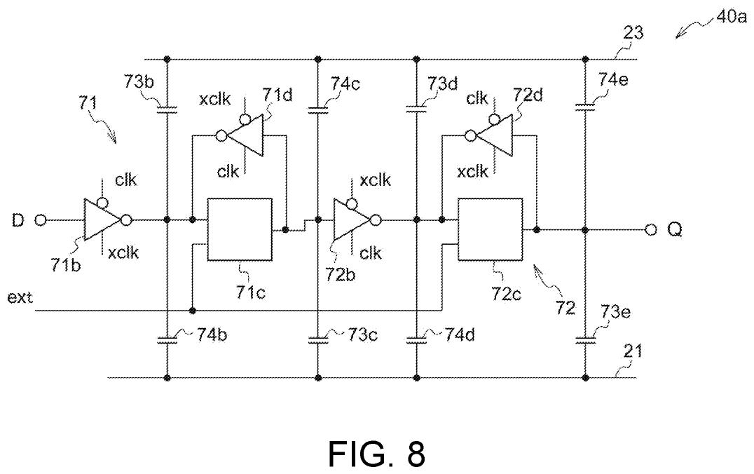

FIG. 8 is a diagram illustrating an exemplary test logic circuit of the semiconductor device according to the present embodiment.

Referring to FIG. 8, an exemplary test logic circuit 40a includes a flip-flop circuit including two of a first latch circuit 71 and a second latch circuit 72 connected in series. The flip-flop circuit has an input D and an output Q. The first latch circuit 71 includes inverting gates 71b and 71d such as tri-state (clocked) inverters and a multi-input logic inverting gate 71c such as a NOR circuit, and the inverting gate 71d and the logic inverting gate 71c form a feedback circuit. The second latch circuit 72 includes inverting gates 72b and 72d such as tri-state inverters and a multi-input logic inverting gate 72c such as a NOR circuit, and the inverting gate 72d and the logic inverting gate 72c form a feedback circuit. The logic inverting gate 71c and the logic inverting gate 72c receive a signal (ext) as set.

The inverting gate 71b and the inverting gate 72d receive a clock (clk) through a p-channel transistor and receive a clock (xclk which is an inversion of clk) through an n-channel transistor. The inverting gate 71d and the inverting gate 72b receive a clock (xclk) through a p-channel transistor and receive a clock (clk) through an n-channel transistor.

The test logic circuit 40a includes capacitors 73b, 73c, 73d, 73c, 74b, 74c, 74d, and 74c (including at least one of a capacitor element or a parasitic capacitor). The capacitors 73b, 73c, 73d, 73c, 74b, 74c, 74d, and 74c are connected to the connection nodes and outputs between the inverting gate and logic inverting gate.

Specifically, the capacitor 73b is connected between the output of the inverting gate 71b and the high-potential power supply line 23, and the capacitor 74b is connected between the output of the inverting gate 71b and the low-potential power supply line 21. The capacitor 73c is connected between the output of the logic inverting gate 71c and the low-potential power supply line 21, and the capacitor 74c is connected between the output of the logic inverting gate 71c and the high-potential power supply line 23. The capacitor 73d is connected between the output of the inverting gate 72b and the high-potential power supply line 23, and the capacitor 74d is connected between the output of the inverting gate 72b and the low-potential power supply line 21. The capacitor 73e is connected between the output of the logic inverting gate 72c and the low-potential power supply line 21, and the capacitor 74e is connected between the output of the logic inverting gate 72c and the high-potential power supply line 23. At least one of the capacitors 73b, 73c, 73d, 73c, 74b, 74c, 74d, and 74c can be applied to the test logic circuit 40a. In addition, at least one of the capacitors 73b, 73c, 73d, 73c, 74b, 74c, 74d, and 74c can be connected to at least one of the input node, output node, and internal node of the test logic circuit 40a.

The capacitances of the capacitors 73b, 73c, 73d and 73e are greater than the capacitance of the capacitors 74b, 74c, 74d, and 74c, respectively.

The exemplary test logic circuit 40a holds the logic value “L” in the first latch circuit 71 and the second latch circuit 72 after the reset is released in response to the signal ext.

The test logic circuit 40a has a characteristic that the logic value “L” easily changes to the logic value “H” due to the connection of capacitors.

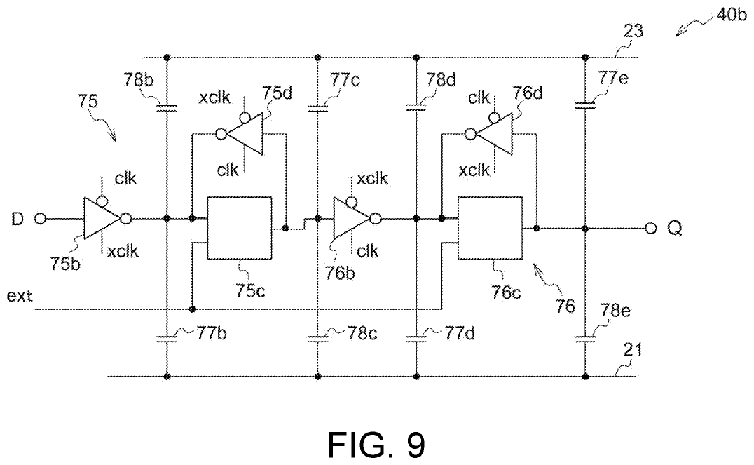

FIG. 9 is a diagram illustrating an exemplary test logic circuit of the semiconductor device according to the present embodiment.

Referring to FIG. 9, an exemplary test logic circuit 40b includes a flip-flop circuit including two of a first latch circuit 75 and a second latch circuit 76 connected in series. Similarly to FIG. 8, the first latch circuit 75 includes inverting gates 75b and 75d such as tri-state inverters and a multi-input logic inverting gate 75c such as a NAND circuit, and the inverting gate 75d and the logic inverting gate 75c form a feedback circuit. The second latch circuit 76 includes inverting gates 76b and 76d such as tri-state inverters and a multi-input logic inverting gate 76c such as a NAND circuit, and the inverting gate 76d and the logic inverting gate 76c form a feedback circuit. The logic inverting gate 75c and the logic inverting gate 76c receive a signal (ext) such as a set signal (set).

The inverting gate 75b and the inverting gate 76d receive a clock (clk) through a p-channel transistor and receive a clock (xclk) through an n-channel transistor. The inverting gate 75d and the inverting gate 76b receive a clock (xclk) through a p-channel transistor and receive a clock (clk) through an n-channel transistor.

The test logic circuit 40b includes capacitors 77b, 77c, 77d, 77c, 78b, 78c, 78d, and 78c (including at least one of a capacitor element or a parasitic capacitor). The capacitors 77b, 77c, 77d, 77c, 78b, 78c, 78d, and 78e are connected to the connection nodes between the inverting gate and logic inverting gate.

Specifically, the capacitor 77b is connected between the output of the inverting gate 75b and the low-potential power supply line 21, and the capacitor 78b is connected between the output of the inverting gate 75b and the high-potential power supply line 23. The capacitor 77c is connected between the output of the logic inverting gate 75c and the high-potential power supply line 23, and the capacitor 78c is connected between the output of the logic inverting gate 75c and the low-potential power supply line 21. The capacitor 77d is connected between the output of the inverting gate 76b and the low-potential power supply line 21, and the capacitor 78d is connected between the output of the inverting gate 76b and the high-potential power supply line 23. The capacitor 77e is connected between the output of the logic inverting gate 76c and the high-potential power supply line 23, and the capacitor 78e is connected between the output of the logic inverting gate 76c and the low-potential power supply line 21.

The capacitances of the capacitors 77b, 77c, 77d, and 77e are greater than the capacitances of the capacitors 78b, 78c, 78d, and 78e, respectively.

The exemplary test logic circuit 40b holds the logic value “H” in the first latch circuit 71 and the second latch circuit 72 after the set is released in response to the signal (ext).

The test logic circuit 40b has a characteristic that the logic value “H” easily changes to the logic value “L” due to the connection of capacitors.

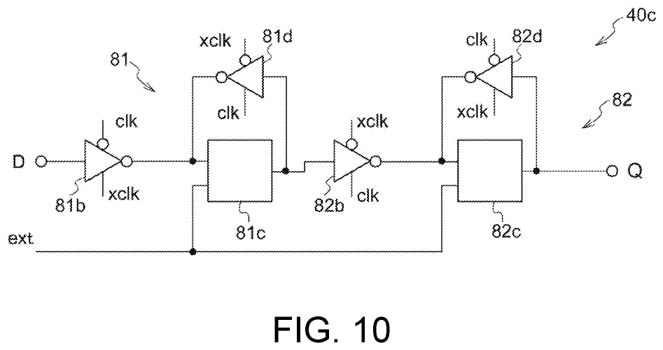

FIG. 10 is a diagram illustrating an exemplary test logic circuit of the semiconductor device according to the present embodiment.

Referring to FIG. 10, an exemplary test logic circuit 40c includes a flip-flop circuit including two of a first latch circuit 81 and a second latch circuit 82 connected in series. The first latch circuit 81 includes inverting gates 81b and 81d such as tri-state inverters and a multi-input logic inverting gate 81c such as a NOR circuit, and the inverting gate 81d and the logic inverting gate 81c form a feedback circuit. The second latch circuit 82 includes inverting gates 82b and 82d such as tri-state inverters and a multi-input logic inverting gate 82c such as a NOR circuit, and the inverting gate 82d and the logic inverting gate 82c form a feedback circuit. The logic inverting gate 81c and the logic inverting gate 82c receive a signal (ext) such as a reset signal (rst).

The inverting gate 81b and the inverting gate 82d receive a clock (clk) through a p-channel transistor and receive a clock (xclk) through an n-channel transistor. The inverting gate 81d and the inverting gate 82b receive a clock (xclk) through a p-channel transistor and receive a clock (clk) through an n-channel transistor.

The inverting gate 81b includes, for example, a p-channel transistor (channel length Lp and channel width Wp) and an n-channel transistor (channel length Ln and channel width Wn). The current drive capability of the p-channel transistor can be expressed by the transistor ratio (channel width Wp/channel length Lp), and the current drive capability of the n-channel transistor can be expressed by the transistor ratio (channel width Wn/channel length Ln). In the inverting gate 81b, the current drive capability of the p-channel transistor is expressed as RTp 81b (=channel width Wp/channel length Lp), and the current drive capability of the n-channel transistor is expressed as RTn 81b (=channel width Wn/channel length Ln). Similarly for other inverting gates and logic gates, the current drive capability of the p-channel transistor and the current drive capability of the n-channel transistor are specified. In addition, in estimating the current drive capability of m-stage vertical stacked transistors, for example, a conversion (W/L/m) in which the channel length L is multiplied by “m” without changing the channel width W is used.

The notation “RTp 81b>RTn 81b” indicates that the current drive capability of the p-channel transistor (RTp 81b) is superior to the current drive capability of the n-channel transistor (RTn 81b).

In the flip-flop circuit of FIG. 10, the following relationship is satisfied.
RTp 81b<RTn 81b
RTp 81c>RTn 81c
RTp 81d<RTn 81d
RTp 82b<RTn 82b
RTp 82c>RTn 82c
RTp 82d<RTn 82d

The exemplary test logic circuit 40c holds the logic value “L” in the first latch circuit 81 and the second latch circuit 82 after the reset is released in response to the signal (ext). The test logic circuit 40c has a characteristic that the logic value “L” easily changes to the logic value “H” due to the drive capability of the transistor.

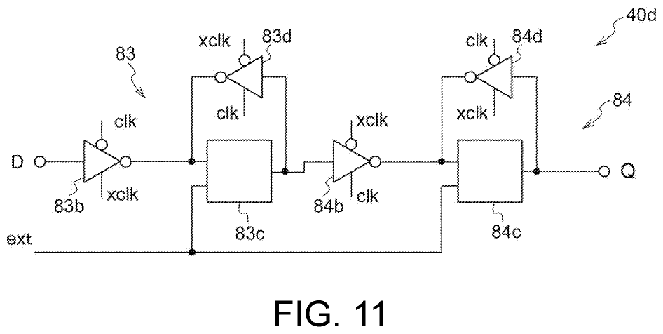

FIG. 11 is a diagram illustrating an exemplary test logic circuit of the semiconductor device according to the present embodiment.

Referring to FIG. 11, an exemplary test logic circuit 40d includes a flip-flop circuit including two of a first latch circuit 83 and a second latch circuit 84 connected in series. The first latch circuit 83 includes inverting gates 83b and 83d such as tri-state inverters and a multi-input logic inverting gate 83c such as a NAND circuit, and the inverting gate 83d and the logic inverting gate 83c form a feedback circuit. The second latch circuit 84 includes inverting gates 84b and 84d such as tri-state inverters and a multi-input logic inverting gate 84c such as a NAND circuit, and the inverting gate 84d and the logic inverting gate 84c form a feedback circuit. The logic inverting gate 83c and the logic inverting gate 84c receive a signal (ext) such as a set signal (rst).

The inverting gate 83b and the inverting gate 84d receive a clock (clk) through a p-channel transistor and receive a clock (xclk which is inversion of clk) through an n-channel transistor. The inverting gate 83d and the inverting gate 84b receive a clock (xclk) through a p-channel transistor and receive a clock (clk) through an n-channel transistor.

Similarly for the inverting gates 83b, 83d, 84b, and 84d and the logic inverting gates 83c and 84c, the current drive capability of the p-channel transistor and the current drive capability of the n-channel transistor are specified.

In the flip-flop circuit of FIG. 11, the following relationship is satisfied.
RTp 83b>RTn 83b
RTp 83c<RTn 83c
RTp 83d>RTn 83d
RTp 84b>RTn 84b
RTp 84c<RTn 84c
RTp 84d>RTn 84d

The exemplary test logic circuit 40d holds the logic value “H” in the first latch circuit 83 and the second latch circuit 84 after the set is released in response to the signal (ext). The test logic circuit 40d has a characteristic that the logic value “H” easily changes to the logic value “L” due to the drive capability of the transistor.

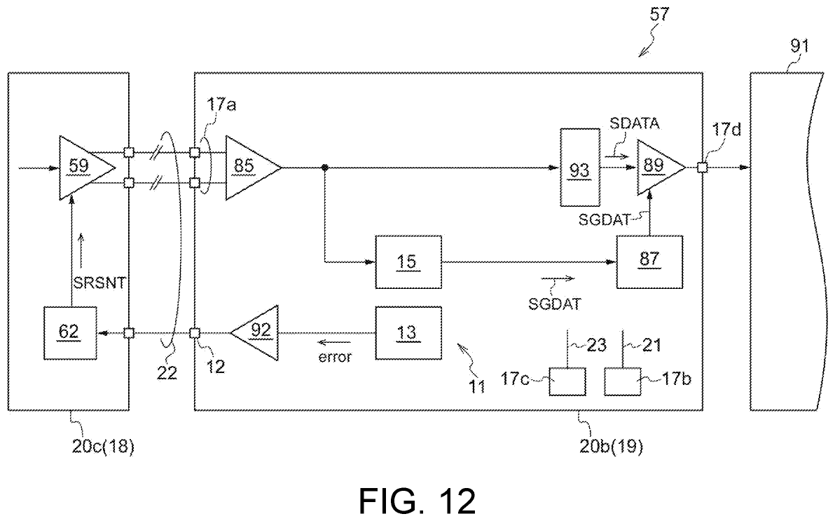

FIG. 12 is a diagram schematically illustrating a driver device according to the present embodiment.

A driver device 57 includes the previously described semiconductor device 11, a receiver 85, a setting circuit 87, and a driver circuit 89. The receiver 85 can be connected to, for example, the electrode 17a. The register 15 receives setting data SGDAT for gamma curve setting from the receiver 85. The setting circuit 87 receives the setting data SGDAT from the receiver 85 through the register 15. The driver circuit 89 is configured to drive a display 91 in accordance with the setting data SGDAT from the setting circuit 87. The output of the driver circuit 89 is connected to the electrode 17d. A storage circuit 93 such as a data latch is provided at the preceding stage of the driver circuit 89. The storage circuit 93 stores image data SDATA to be displayed and provides the image data to the driver circuit 89.

The receiver 85, the driver circuit 89, the setting circuit 87, and the storage circuit 93 are provided on the substrate 19. The collation result (error) of the collation circuit 31 is output from another electrode 12 to the outside of the substrate 19. An output circuit 92 is connected between the test circuit 13 and the electrode 12.

The exemplary register 15 can be located closer to, for example, the test circuit 13 than the receiver 85.

The receiver 85 can receives, for example, a data signal in a serial format. The signal in a serial format can be converted to a data signal in a parallel format by the receiver 85 or another circuit.

The driver device 57 can include a first semiconductor chip 20b and a second semiconductor chip 20c. The first semiconductor chip 20b has the test circuit 13, the register 15, the receiver 85, the setting circuit 87, and the driver circuit 89 mounted on the substrate 19. The driver device 57 can further include a connection structure 22 that connects the first semiconductor chip 20b and the second semiconductor chip 20c to each other, and the connection structure 22 can include, for example, a bonding wire.

The second semiconductor chip 20c can include a transmitter 59 connected to the receiver 85 through the connection structure 22 and an input circuit 62 connected to the output circuit 92 through the connection structure 22. A second substrate 18 including semiconductors is used for the second semiconductor chip 20c. The input circuit 62 sends a retransmission request signal SRSNT to the transmitter 59 in a case where the collation result (error) indicates an expected value mismatch. The transmitter 59 retransmits data such as the setting data SGDAT in response to the retransmission request signal SRSNT. The register 15 stores the setting data SGDAT, for example, when the setting data SGDAT is retransmitted.

According to the above embodiment, it is possible to provide the semiconductor device 11 capable of detecting the possibility of data corruption in the register 15 configured to statically hold data, and the driver device 57 including the semiconductor device 11.

The present embodiment has various aspects as shown below.

According to a first aspect of the present embodiment, there is provided a semiconductor device including: at least one test circuit connected to a low-potential power supply line and a high-potential power supply line; a register provided in a circuit different from the test circuit and connected to the low-potential power supply line and the high-potential power supply line; an electrode configured to enable at least one of inputting and outputting a signal and connectable to the outside of the semiconductor device; and a substrate that has the electrode, the register, and the test circuit mounted thereon and includes a semiconductor, wherein the test circuit includes at least one test logic circuit that includes the same transistor connection as the register, at least one collation circuit that receives an output signal of the test logic circuit and an output signal from an expected value providing circuit and collates a logic value of the output signal of the test logic circuit with a logic value of the output signal from the expected value providing circuit, and an alert circuit that, in a case where the collation circuit indicates a mismatch of the collation, generates an alert signal indicating the mismatch, the test logic circuit is configured to store a logic value to be collated, and the register is connected to the electrode through one or a plurality of circuits or directly.

In the semiconductor device of a second aspect according to the first aspect, the test logic circuit may include a first test logic circuit that includes the same transistor connection as the register, and a second test logic circuit that includes the same transistor connection as the register, the collation circuit may include a first collation circuit configured to receive an output signal of the first test logic circuit and a first output signal from the expected value providing circuit and to collate a logic value of the output signal of the first test logic circuit with a logic value of the first output signal from the expected value providing circuit, and a second collation circuit configured to receive an output signal of the second test logic circuit and a second output signal from the expected value providing circuit and to collate a logic value of the output signal of the second test logic circuit with a logic value of the second output signal from the expected value providing circuit, and the logic value of the first test logic circuit and the logic value of the second test logic circuit may be different from each other.

In the semiconductor device of a third aspect according to the first or second aspect, a quantity of the test logic circuit may be two or more, and the semiconductor device may further include an OR gate that receives output signals of all the test logic circuits through the collation circuit.

In the semiconductor device of a fourth aspect according to any one of the first to third aspects, the test logic circuit includes at least one flip-flop circuit, the test circuit includes a first capacitor connected between the high-potential power supply line and at least any connection node of an output node of the flip-flop circuit, an input node of the flip-flop circuit, and an internal node of the flip-flop circuit, and a second capacitor connected between the connection node of the flip-flop circuit and the low-potential power supply line, and a capacitance of the first capacitor is different from a capacitance of the second capacitor.

In the semiconductor device of a fifth aspect according to any one of the first to fourth aspects, the test logic circuit includes at least one flip-flop circuit, the flip-flop circuit includes at least one negative logic gate and a tri-state inverter, the negative logic gate and the tri-state inverter each have a p-channel transistor and an n-channel transistor, a transistor ratio of the p-channel transistor and a transistor ratio of the n-channel transistor are different from each other, and the transistor ratio indicates a ratio between channel width and channel length of the p-channel transistor and the n-channel transistor.

In the semiconductor device of a sixth aspect according to the second aspect, the first test logic circuit may include a series connection of a plurality of first flip-flop circuits connected in series, the second test logic circuit may include a series connection of a plurality of second flip-flop circuits connected in series, the series connection of the first flip-flop circuits may be configured to receive one of a set signal and a reset signal, and the series connection of the second flip-flop circuits may be configured to receive the other of the set signal and the reset signal.

In the semiconductor device of a seventh aspect according to the second or sixth aspect, the first test logic circuit includes at least one first flip-flop circuit, the second test logic circuit includes at least one second flip-flop circuit, the test circuit includes a first capacitor connected between the high-potential power supply line and at least one connection node of an output node of the first flip-flop circuit and an internal node of the first flip-flop circuit, and a second capacitor connected between the connection node of the first flip-flop circuit and the low-potential power supply line, and a capacitance of the first capacitor is different from a capacitance of the second capacitor.

In the semiconductor device of an eighth aspect according to the second, sixth, or seventh aspect, the first test logic circuit includes at least one first flip-flop circuit, the second test logic circuit includes at least one second flip-flop circuit, one or both of the first flip-flop circuit and the second flip-flop circuit include at least one negative logic gate and a tri-state inverter, the negative logic gate and the tri-state inverter each have a p-channel transistor and an n-channel transistor, a transistor ratio of the p-channel transistor and a transistor ratio of the n-channel transistor are different from each other, and the transistor ratio indicates a ratio between channel width and channel length of the p-channel transistor and the n-channel transistor.

According to a ninth aspect of the present embodiment, there is provided a driver device including: the semiconductor device according to any one of the first to eighth aspects; a receiver provided on the substrate; a setting circuit that receives setting data for gamma curve setting from the receiver through the register and is provided on the substrate; and a driver circuit configured to receive the setting data from the setting circuit and to drive a display, and provided on the substrate, wherein a collation result of the collation circuit is output to the outside of the substrate.

In the driver device of a tenth aspect according to the ninth aspect, the semiconductor device, the receiver, the setting circuit, and the driver circuit are included in a first semiconductor chip, the driver device further includes a second semiconductor chip and a connection structure that connects the first semiconductor chip and the second semiconductor chip to each other, and the second semiconductor chip includes a transmitter connected to the receiver through the connection structure, an input circuit that receives the collation result of the collation circuit through the connection structure and sends a retransmission request signal to the transmitter in a case where the collation result indicates an expected value mismatch, and a second substrate that has the input circuit and the transmitter mounted thereon and includes a semiconductor.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device comprising:
at least one test circuit connected to a low-potential power supply line and a high-potential power supply line;
a register provided in a circuit different from the test circuit and connected to the low-potential power supply line and the high-potential power supply line;
an electrode configured to enable at least one of inputting and outputting a signal and connectable to outside of the semiconductor device; and
a substrate that has the electrode, the register, and the test circuit mounted thereon and includes a semiconductor,
wherein the test circuit includes
at least one test logic circuit that includes a same transistor connection as the register,
at least one collation circuit that receives an output signal of the test logic circuit and an output signal from an expected value providing circuit and collates a logic value of the output signal of the test logic circuit with a logic value of the output signal from the expected value providing circuit, and
an alert circuit that, in a case where the collation circuit indicates a mismatch of the collation, generates an alert signal indicating the mismatch,
the test logic circuit is configured to store a logic value to be collated, and
the register is connected to the electrode through one or a plurality of circuits or directly.

2. The semiconductor device according to claim 1, wherein the test logic circuit includes
a first test logic circuit that includes the same transistor connection as the register, and
a second test logic circuit that includes the same transistor connection as the register,
the collation circuit includes
a first collation circuit configured to receive an output signal of the first test logic circuit and a first output signal from the expected value providing circuit and to collate a logic value of the output signal of the first test logic circuit with a logic value of the first output signal from the expected value providing circuit, and
a second collation circuit configured to receive an output signal of the second test logic circuit and a second output signal from the expected value providing circuit and to collate a logic value of the output signal of the second test logic circuit with a logic value of the second output signal from the expected value providing circuit, and
the logic value of the first test logic circuit and the logic value of the second test logic circuit are different from each other.

3. The semiconductor device according to claim 1, wherein a quantity of the test logic circuit is two or more, and
the semiconductor device further includes an OR gate that receives output signals of all the test logic circuits through the collation circuit.

4. The semiconductor device according to claim 1, wherein the test logic circuit includes at least one flip-flop circuit,
the test circuit includes: a first capacitor connected between the high-potential power supply line and at least any connection node of an output node of the flip-flop circuit, an input node of the flip-flop circuit, and an internal node of the flip-flop circuit; and a second capacitor connected between the connection node of the flip-flop circuit and the low-potential power supply line, and
a capacitance of the first capacitor is different from a capacitance of the second capacitor.

5. The semiconductor device according to claim 1, wherein the test logic circuit includes at least one flip-flop circuit,
the flip-flop circuit includes at least one negative logic gate and a tri-state inverter,
the negative logic gate and the tri-state inverter each have a p-channel transistor and an n-channel transistor,
a transistor ratio of the p-channel transistor and a transistor ratio of the n-channel transistor are different from each other, and
the transistor ratio indicates a ratio between channel width and channel length of the p-channel transistor and the n-channel transistor.

6. The semiconductor device according to claim 2, wherein the first test logic circuit includes a series connection of a plurality of first flip-flop circuits connected in series,
the second test logic circuit includes a series connection of a plurality of second flip-flop circuits connected in series,
the series connection of the first flip-flop circuits is configured to receive one of a set signal and a reset signal, and
the series connection of the second flip-flop circuits is configured to receive the other of the set signal and the reset signal.

7. The semiconductor device according to claim 2, wherein the first test logic circuit includes at least one first flip-flop circuit,
the second test logic circuit includes at least one second flip-flop circuit,
the test circuit includes: a first capacitor connected between the high-potential power supply line and at least one connection node of an output node of the first flip-flop circuit and an internal node of the first flip-flop circuit; and a second capacitor connected between the connection node of the first flip-flop circuit and the low-potential power supply line, and
a capacitance of the first capacitor is different from a capacitance of the second capacitor.

8. The semiconductor device according to claim 2, wherein the first test logic circuit includes at least one first flip-flop circuit,
the second test logic circuit includes at least one second flip-flop circuit,
one or both of the first flip-flop circuit and the second flip-flop circuit include at least one negative logic gate and a tri-state inverter,
the negative logic gate and the tri-state inverter each have a p-channel transistor and an n-channel transistor,
a transistor ratio of the p-channel transistor and a transistor ratio of the n-channel transistor are different from each other, and
the transistor ratio indicates a ratio between channel width and channel length of the p-channel transistor and the n-channel transistor.

9. A driver device comprising:
the semiconductor device according to claim 1;
a receiver provided on the substrate;
a setting circuit that receives setting data for gamma curve setting from the receiver through the register and is provided on the substrate; and
a driver circuit configured to receive the setting data from the setting circuit and to drive a display, and provided on the substrate,
wherein a collation result of the collation circuit is output to outside of the substrate.

10. The driver device according to claim 9, wherein the semiconductor device, the receiver, the setting circuit, and the driver circuit are included in a first semiconductor chip,
the driver device further includes a second semiconductor chip and a connection structure that connects the first semiconductor chip and the second semiconductor chip to each other, and
the second semiconductor chip includes
a transmitter connected to the receiver through the connection structure,
an input circuit that receives the collation result of the collation circuit through the connection structure and sends a retransmission request signal to the transmitter in a case where the collation result indicates an expected value mismatch, and
a second substrate that has the input circuit and the transmitter mounted thereon and includes a semiconductor.
